(19) United States
(12) Patent Application Publication
(10) Pub. No.: US 2009/0085173 A1
(43) Pub. Date: Apr. 2, 2009

(54) SIDEWALL PROTECTION LAYER

(76) Inventors: Juergen Boemmels, Dresden (DE); Frank Feustel, Dresden (DE); Ralf Richter, Dresden (DE)

Correspondence Address: WILLIAMS, MORGAN & AMERSON, 10333 RICHMOND, SUITE 1100, HOUSTON, TX, 77042, US

(21) Appl. No.: 12/056,356

(22) Filed: Mar. 27, 2008

(30) Foreign Application Priority Data
Sep. 29, 2007 (DE) 10 2007 046 846.8

(51) Int. Cl. H01L 23/58; H01L 21/311; H01L 21/44

(52) U.S. Cl. 257/635; 438/700; 438/653; 257/E23.141

(57) ABSTRACT

The present disclosure generally relates to forming a metallization layer in a semiconductor device. In particular, this disclosure concerns the damascene inlay technique in low-k dielectric layers. Etching trenches and vias in low-k dielectric materials leads to uneven and porous sidewalls of the trenches and vias due to the porous nature of the low-k dielectric materials. Thus, smooth and dense sidewalls cannot be achieved, which is a prerequisite for an effective barrier layer, which prevents copper from being diffused into the low-k dielectric material. As a consequence, process tolerances are high and the reliability of the semiconductor device is reduced. The present disclosure overcomes these drawbacks by a surface treatment of the sidewalls of trenches and vias in order to densify the surface such that the following barrier layer may more effectively prevent copper from diffusing into the low-k or ultra high-k dielectric material.

### BACKGROUND OF THE INVENTION

1. Field of the Invention

The present disclosure generally relates to the field of fabrication of integrated circuits, and, more particularly, to the formation of a dielectric protection layer on a sidewall of vias and trenches etched into a layer of low-k material that is used in a damascene inlay scheme.

2. Description of the Related Art

In an integrated circuit, a huge number of circuit elements, such as transistors, capacitors, resistors and the like, are formed in or on an appropriate substrate, usually in a substantially planar configuration. Due to the large number of circuit elements and the required complex layout of the integrated circuits for advanced applications, generally the electrical connection of the individual circuit elements may not be established within the same level on which the circuit elements are manufactured, but requires one or more additional “wiring” layers, also referred to as metallization layers. These metallization layers generally include metal lines, providing the intra-level electrical connection, and also include a plurality of inter-level connections, also referred to as vias, wherein the metal lines and vias may also be commonly referred to as interconnects.

Due to the continuous shrinkage of the feature sizes of circuit elements in modern integrated circuits, the number of circuit elements for a given chip area, that is the packing density, also increases, thereby requiring an even larger increase in the number of electrical interconnections to provide the desired circuit functionality. Therefore, the number of stacked metallization layers may increase as the number of circuit elements per chip area becomes larger. Since the fabrication of a plurality of metallization layers entails extremely challenging issues to be solved, such as the mechanical, thermal and electrical reliability of a plurality of stacked metallization layers that are required, for example, for sophisticated based microprocessors, semiconductor manufacturers are increasingly replacing the well-known metallization metal aluminum by a metal that allows higher current densities and hence allows a reduction in the dimensions of the interconnections. For example, copper is a metal generally considered to be a viable candidate for replacing aluminum, due to its superior characteristics in view of higher resistance against electromigration and significantly lower electrical resistivity when compared with aluminum. In spite of these advantages, copper also exhibits a number of disadvantages regarding the processing and handling of copper in a semiconductor facility. For instance, copper may not be efficiently applied onto a substrate in larger amounts by well-established deposition methods, such as chemical vapor deposition (CVD) and physical vapor deposition (PVD), and also may not be effectively patterned by the usually employed anisotropic etch procedures due to copper's characteristic to form non-volatile reaction products. In manufacturing metallization layers including copper, the so-called damascene inlaid technique is therefore preferably used, wherein a dielectric layer is first applied and then patterned to define trenches and vias therein, which are subsequently filled with the metal, such as copper.

A further major drawback of copper is its propensity to readily diffuse in silicon dioxide and other dielectric materials. It is therefore usually necessary to employ a so-called barrier material in combination with a copper-based metallization to substantially avoid any out-diffusion of copper into the surrounding dielectric material, as copper may then readily migrate to sensitive semiconductor areas, thereby significantly changing the characteristics thereof. Moreover, in view of copper integrity, the barrier material may be selected to suppress diffusion of unwanted materials, such as oxygen, fluorine and the like, towards the copper, thereby reducing the risk for corrosion and oxidation. Since the dimensions of the trenches and vias have currently reached a width or a diameter of approximately 0.1 μm and even less with an aspect ratio of the vias of about 5 or more, the deposition of a barrier layer reliably on all surfaces of the vias and trenches and subsequent filling thereof with copper substantially without voids is a most challenging issue in the fabrication of modern integrated circuits.

Currently, the formation of a copper-based metallization layer is accomplished by patterning an appropriate dielectric layer and depositing the barrier layer, for example comprised of tantalum (Ta) and/or tantalum nitride (TaN), by advanced PVD techniques, such as sputter deposition. For the deposition of a barrier layer of approximately 10-50 nm in vias having an aspect ratio of 5 or even more, enhanced sputter tools are usually employed. Such tools offer the possibility of ionizing a desired fraction of the target atoms after sputtering them off the target, thereby enabling, to a certain degree, the control of the bottom coverage and the sidewall coverage in the vias. Thereafter, the copper is filled in the vias and trenches, wherein electroplating has proven to be a viable process technique, since it is capable of filling the vias and trenches with a high deposition rate, compared to CVD and PVD rates, in a so-called bottom-up regime, in which the openings are filled starting at the bottom in a substantially void-free manner. Generally, in electroplating a metal, an external electric field is applied between the surface to be plated and the plating solution. Since substrates for semiconductor production may be contacted at restricted areas, usually at the perimeter of the substrate, a conductive layer covering the substrate and the surfaces that are to receive a metal has to be provided. Although the barrier layer previously deposited over the patterned dielectric may act as a current distribution layer, it turns out, however, that, in view of crystallinity, uniformity and adhesion characteristics, preferably a so-called seed layer is required in the subsequent electroplating process to obtain copper trenches and vias having the required electrical and mechanical properties. The seed layer, usually comprised of copper, is typically applied by sputter deposition using substantially the same process tools as are employed for the deposition of the barrier layer.

FIGS. 1a-1c illustrate a process sequence for a dual damascene structure according to the above explained state of the art. FIG. 1a illustrates a structure wherein a second metallization level is placed onto a first metallization level. In the first metallization level, a conductive line 102 is embedded in a dielectric material 101. In a second metallization level, a trench 104 and a via 105 are etched into a second dielectric material 103 to expose a part of the underlying wiring 102. Thus, an electrical connection between the first metallization layer and the second metallization layer may be achieved. Afterwards, as illustrated in FIG. 1b, a metallic barrier layer 106 is deposited, for instance, by sputtering 107. Subsequently, as shown in FIG. 1c, the via 105 and the trench 104 are filled with metal 110. For instance, in an electroplating process or an electroless plating process, the metal 110 is deposited from an electrolyte solution 108. In the case of electroplating, a voltage is applied between an anode and a seed layer deposited on the barrier layer, which serves as a cathode. In this case, a current 109 flows from the anode to the cathode and deposits charged metal particles, for instance copper, on the barrier and seed layer, thus filling the via 105 and the trench 104. In order to achieve a complete fill of the trench and the via, these structures are overfilled. The excess material then has to be removed in a subsequent polishing process (not shown). As outlined above, the filling process alone is a complex process requiring, for instance, an additional metallic seed layer which is not shown in the figures and which is also not described in detail here.

For dimensions of 0.1 μm and less of vias in future device generations, the sputter deposition of extremely thin metal layers having a high degree of conformity as required for the barrier layer and the seed layer may become a limiting factor, since the step coverage characteristics of the above-described advanced sputter tools may not be further enhanced without significant modifications of these tools, which seems not to be a straightforward development. Especially the deposition of the seed layer may not be performed in a straight-forward manner by PVD as here the uniformity of the seed layer, contrary to the barrier layer “only” requiring a sufficient and complete coverage of the inner surfaces of the openings, determines to a certain degree the uniformity of the following electroplating process. More-over, PVD techniques producing extremely thin layers appropriate for barrier layers may result, when applied to the formation of seed layers, in an increased electric resistance, thereby reducing an initial deposition rate of the subsequent electroplating process.

As a consequence, alternative deposition techniques for highly sophisticated applications have been proposed for barrier deposition and seed deposition for copper-based lines. For example, CVD techniques have been developed for forming highly conformal barrier and seed layers, thereby taking advantage of CVD's inherent superior behavior with respect to step coverage compared to sputter deposition. Similarly, self-limiting CVD-based deposition techniques, known as atomic layer deposition (ALD), have been developed for several materials in order to provide extremely thin yet reliable barrier or seed layers within high aspect ratio openings.

As the size of the individual circuit elements is significantly reduced, thereby improving, for example, the switching speed of transistor elements, the available floor space for the various components, such as drain and source regions, gate electrodes of transistors and interconnect lines electrically connecting the individual circuit elements, is also decreased. Consequently, the dimensions of these components have to be reduced to compensate for a reduced amount of available floor space and for an increased number of circuit elements provided per chip. In integrated circuits having minimum pattern dimensions of approximately 0.35 μm and less, a limiting factor of device performance is the signal propagation delay caused by the switching speed of the involved transistor elements. As the channel length of these elements has reached 0.18 μm and less, it turns out, however, that the signal propagation delay is no longer limited by the field effect transistors but is limited, owing to the increased circuit density, by the close proximity of the metal lines in the wiring levels, since the line-to-line capacitance is increased in combination with a reduced conductivity of the lines due to a reduced cross-sectional area. The parasitic RC (resistance/capacitance) time constants therefore may require the introduction of a new type of dielectric material, preferably in combination with a highly conductive metal.

Traditionally, metallization layers are formed by a dielectric layer stack including, for example, silicon dioxide and/or silicon nitride, with aluminum as the typical metal. Since aluminum exhibits significant electromigration at higher current densities, commonly in highly sophisticated integrated circuits, aluminum is replaced by copper having a significantly lower electrical resistance and a higher resistivity against electromigration. Moreover, the well-established and well-known dielectric materials silicon dioxide (k≈4.2) and silicon nitride (k>5) are increasingly replaced by low-k materials to reduce the parasitic capacitance. However, the transition from the well-known and well-established aluminum/silicon dioxide metallization layer to a low-k dielectric/copper metallization layer is associated with a plurality of issues to be dealt with.

Low-k dielectric materials that have been successfully used in chip technology include, among others, fluorine doped silicon dioxide, carbon doped silicon dioxide, porous silicon dioxide, porous carbon doped silicon dioxide, spin-on organic polymeric dielectrics, e.g., polyimide, polynorbornenes, benzocyclobutene, PTFE, SiLK from Dow Chemical, and porous SiLK, spin-on silicone based polymeric dielectrics, e.g., hydrogen silsesquioxane (HSQ) and methylsilsesquioxane (MSQ).

When replacing the high-k material silicon dioxide by a low-k material, the situation in forming the via and trench is quite different to the situation shown in FIGS. 1a-1c. Low-k dielectric materials do not provide smooth and dense sidewall surfaces of etched vias and trenches, due to the properties of the used materials, which are often porous materials in order to lower the dielectric constant. The damages lead to out-gassing and porous barrier layers which in turn leads to reliability problems, to increased resistance, and to a reduced speed of the devices. One of these problems is illustrated in FIG. 2. In FIG. 2, the reference numerals 201 and 202 represent an underlying wiring layer with a conductive line 202 embedded in a dielectric material 201. A low-k dielectric material 203 is provided thereover and a trench 204 and a via 205 is etched into the low-k material. Since the etch process leads to a rough and damaged surface of the sidewalls 207 of the trench 204 and the via 205, the sidewalls 207 cannot be uniformly covered with the barrier layer 206 which leads to further defects in the sidewall such that a metal, for instance copper, which is deposited in the via 205 and the trench 204, may diffuse into the low-k dielectric material 203. Vice versa, gases contained in the low-k dielectric material 203 may diffuse to the metal and lead to corrosion.

The present disclosure is directed to various techniques and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally relates to forming a metallization layer in a semiconductor device. In particular, this disclosure concerns the inlay and dual inlay damascene technique in low-k dielectric layers. Due to the fact that sidewalls of trenches and vias in low-k dielectric materials have uneven and porous surfaces due to the porous nature of the low-k dielectric materials, smooth and dense sidewalls cannot be achieved, which is a prerequisite for an effective barrier layer which prevents copper from being defused into the low-k dielectric material. As a consequence, process tolerances are high and the reliability of the semiconductor device is reduced. The present disclosure overcomes these drawbacks by a surface treatment of the sidewalls of trenches and vias in order to fill the surface damages in the sidewalls such that the following barrier layer may more effectively prevent copper from defusing into the low-k or ultra low-k dielectric material. In one illustrative embodiment, there is provided a method of manufacturing a semiconductor device comprising depositing a low-k dielectric material onto a surface, forming at least one of a via and a trench into the low-k dielectric material, performing a protection treatment of sidewalls of the via and the trench for densifying and smoothing the sidewalls, and coating the protection-treated sidewalls with a barrier layer.

In another illustrative embodiment, there is provided a method of manufacturing a semiconductor device having at least one metallization layer, wherein each metallization layer comprises a layer of low-k dielectric material including at least one of a via and a trench formed in the layer of low-k dielectric material, and wherein the method comprises coating sidewalls of the via and the trench with a dielectric material. Coating the sidewalls comprises forming a thin film on the semiconductor device to cover a top surface of the low-k dielectric material, the sidewalls of the via and the trench and the bottom surface of the via and the trench, and removing the thin film from a top surface of the low k-dielectric material and the bottom surface of the via and the trench by non-isotropic etching to expose a wiring portion at the bottom surface of the via. The method further comprises coating the protection-treated sidewalls with a barrier layer and filling the via and the trench with a metal.

In yet another illustrative embodiment, there is provided a semiconductor device comprising at least one metallization layer, each metallization layer including at least one of a via and a trench formed in a layer of low-k dielectric material and filled with copper, wherein sidewalls of the via and the trench are coated with a thin film comprising at least one of silicon oxide (SiO₂), silicon nitride (Si₃N₄) and silicon carbide (SiC) and a polymer with surface-smoothing properties that withstands temperatures of less than 300° C. and a conductive barrier layer is formed on the thin film.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically show cross-sectional views of a semiconductor device during various manufacturing stages in filling an opening formed in a patterned dielectric layer in accordance with the state of the art;

FIG. 2 illustrates a problem of the state of the art according to FIGS. 1a-1c; and

FIGS. 3a-3c schematically show cross-sectional views of a semiconductor device during various manufacturing stages in filling an opening formed in a patterned dielectric layer in accordance with the present disclosure.

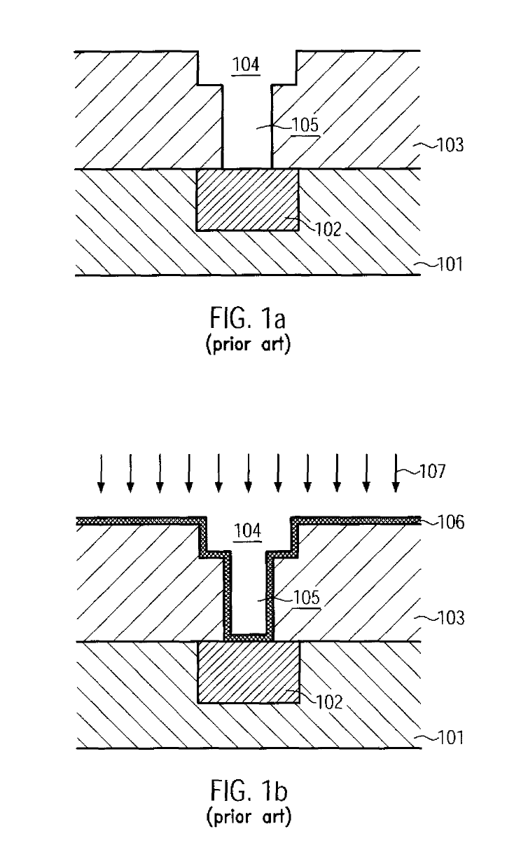

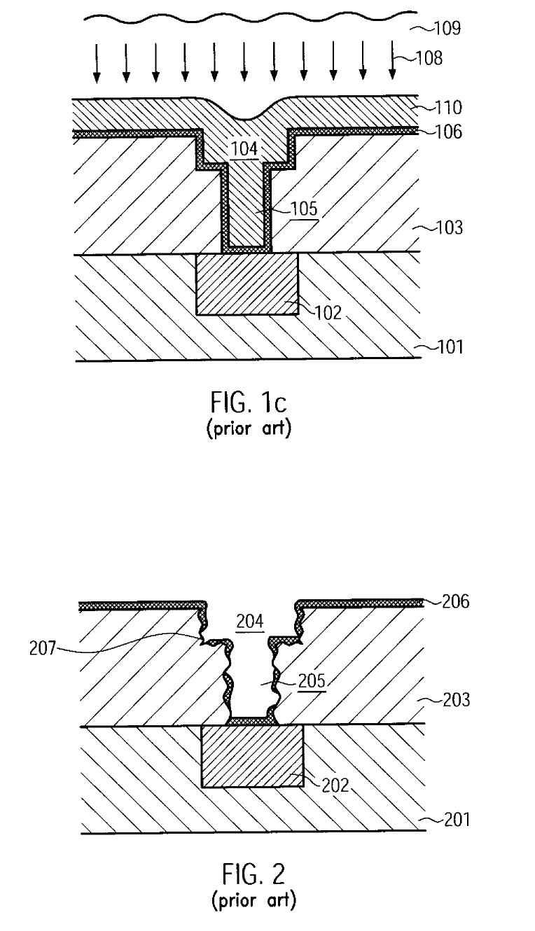

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to forming a metallization layer in a semiconductor device. In particular, this disclosure concerns the damascene inlay technique in low-k dielectric layers. As pointed out above, etching trenches and vias in low-k dielectric materials leads to uneven and porous sidewalls of the trenches and vias due to the porous nature of the low-k dielectric materials. Thus, smooth and dense sidewalls cannot be achieved, which is a prerequisite for an effective barrier layer in order to prevent copper from being defused into the low-k dielectric material. As a consequence, process tolerances are high and the reliability of the semiconductor device is reduced. The present disclosure over-comes these drawbacks by a surface treatment of the sidewalls of trenches and vias in order to densify the surface such that the following barrier layer may more effectively prevent copper from defusing into the low-k or ultra low-k dielectric material. Densifying means that pores in the ultra low-k dielectric material are substantially sealed and the roughness of the surface due to etching the low-k dielectric material is reduced or smoothed such that an improved coverage of the subsequent barrier layer is achieved.

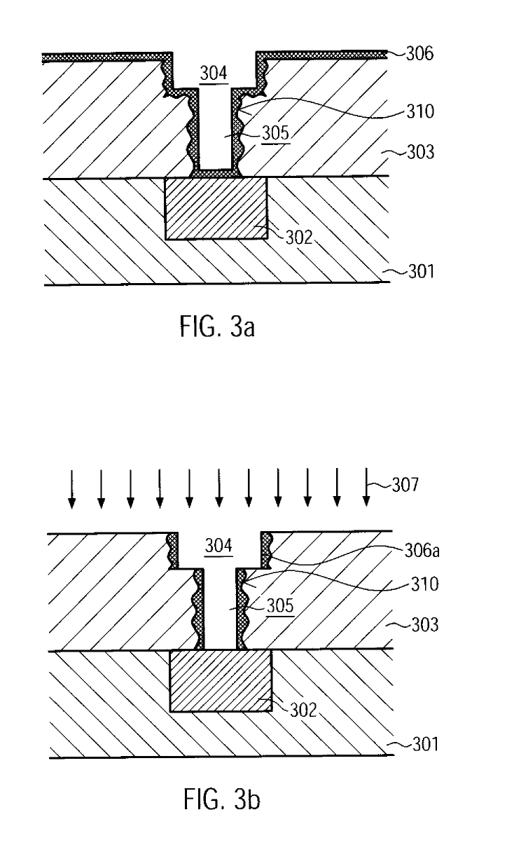

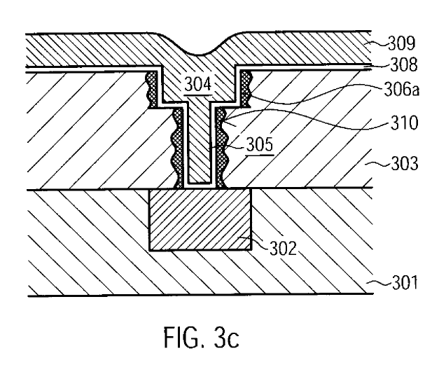

In the following, an illustrative embodiment is explained in connection with FIGS. 3a-3c. FIG. 3a shows a manufacturing state wherein vias and trenches have been etched into a low-k dielectric material 303. A top surface of the low-k dielectric material and the sidewalls of the via and the trench, as well as the bottom surface of the via, have been coated with a thin dielectric film 306 to densify and smooth the sidewalls of the via and the trench. In FIG. 3a, reference numerals 301 and 302 designate a first completed wiring layer, whereby numeral 302 designates the conductive portion, e.g., a metal line comprising copper, that is embedded in a dielectric material designated with reference numeral 301. Reference numeral 303 designates a layer of low-k dielectric material into which a trench 304 and a via 305 were etched. The via 305 was etched completely through the low-k dielectric film 303 to reach the underlying metal line 302 in order to form an interconnection between different layer levels. Reference numeral 310 designates the surface of the sidewalls of the trench 304 and the via 305. As it is illustrated in FIG. 3a, the sidewalls of the trench 304 and the via 305 have damages, which has been illustrated as having a rough surface 310. In FIG. 3a, the damages have been illustrated oversized for illustrative purposes. Reference numeral 306 designates a layer of dielectric material which is the result of the surface treatment in order to density and smooth out the damaged surface 310 of the sidewalls. The thickness of the thin dielectric film 306 depends on the particular method of forming this film which will be described in more detail below. Since the via 305 should provide an interconnection to the underlying wire line 302, the dielectric layer 306 on the bottom of the via 305 has to be removed. This is illustrated in FIG. 3b.

FIG. 3b illustrates an anisotropic etch process wherein the dielectric layer 306 at the top surface of the low-k dielectric film 303 and on the bottom surface of the via 305 is removed. Anisotropic etching means that the etch rate in a vertical direction is much higher than in a horizontal direction in terms of a coordinate system of the illustration in FIG. 3b. Reactive ion etching (RIE) or sputter etching may be used to remove the thin dielectric film 306 from the bottom surface of the via 305 and the top surface of the low-k dielectric film 303. Such dry etch processes also have a smoothing effect on the sidewalls of the trench 304 and the via 305 and lead to a thin sidewall protection film 306a. Reference numeral 307 designates the direction into which ions are accelerated to remove the material physically (sputter etching) and/or chemically (reactive ion etching). Although the dry etch process is intended to remove the material from the bottom of the via 305, an appropriately adjusted dry etch process with an appropriately balanced chemical reaction component and physical removal may support the general object to densify and smooth out the sidewall surface of the trench 304 and via 305.

Subsequently, a barrier layer 308 is formed to cover the top surface of the low-k dielectric thin film, the sidewall protection film 306a of the trench 304 and the via 305 and the bottom surface of the via 305, as shown in FIG. 3c. The barrier layer 308 may be comprised of any appropriate material, such as tantalum, tantalum nitride, titanium, titanium nitride, tungsten, tungsten nitride or any other appropriate compound having the desired characteristics with respect to endowing the metal within the trenches 304 and via 305 with the required mechanical and chemical integrity. In some illustrative embodiments, the barrier layer 308 may be formed of one or more of the following compounds: cobalt, tungsten, phosphorous (COWP) and/or cobalt, tungsten, boron (COWB) and/or cobalt, boron (CoB) and/or molybdenum, nickel, boron (MoNiB), and the like. The barrier layer is intended to prevent copper from diffusing into surrounding materials, which would degrade their properties. Since silicon forms deep level traps when dealt with copper, and since in addition low-k materials are often porous materials, copper-containing regions have to be thoroughly separated from the surrounding dielectric material. Generally, a barrier layer must have high electrical conductivity in order to maintain a good electronic contact, while preventing copper from diffusing into surrounding dielectric material. In an illustrative embodiment, the barrier layer may be deposited by advanced PVD techniques, such as sputter deposition. For the deposition of a barrier layer of approximately 10-50 nm in vias having an aspect ratio of 5 or even more, enhanced sputter tools are usually employed. Such tools offer the possibility to ionize a desired fraction of the target atoms after sputtering them off the target, thereby enabling, to a certain degree, the control of the bottom coverage and sidewall coverage in the vias. Thereafter, the copper 309 is filled into the vias 305 and trenches 304, wherein electro-plating has proved to be a viable process technique, since it is capable of filling the vias and trenches with a deposition rate, compared to CVD and PVD rates, in a so-called bottom-up regime, in which the openings are filled starting at the bottom in a substantially void-free manner. Generally, in electroplating a metal, an external electric field is applied between the surface to be plated and the plating solution. Since substrates for semiconductor production may be contacted at restricted areas, usually at the perimeter of the substrate, a conductive layer covering the substrate and the surface that are to receive a metal has to be provided. Although the barrier layer previously deposited over the patterned dielectric may act as a current distribution layer, it turns out, however, that, in view of crystallinity, uniformity and adhesion characteristics, preferably a so-called seed layer is advantageous in the subsequent electroplating process to obtain copper trenches and vias having the required electrical and mechanical properties. The seed layer, usually comprised of copper, is typically applied by sputter deposition using substantially the same process tools as are employed for the deposition of the barrier layer.

For dimensions of 0.1 μm and less of vias, alternative deposition techniques have to be applied to achieve thin and uniform barrier and seed layers. For instance, appropriately designed CVD techniques may be used for forming highly conformal barrier and seed layers, thereby taking advantage of CVD's inherent superior behavior with respect to the step coverage compared to the sputter deposition. Similarly, self limiting CVD-based deposition techniques, known as atomic layer deposition (ALD), have been developed for several materials in order to provide extremely thin yet reliable barrier or seed layers with high aspect ratio openings.

As already pointed out in connection with FIGS. 3a-3b, the primary purpose of the sidewall protection layer 306 and 306a is to densify and smooth out the surface 310 of the sidewalls of the trench and the via 305. Thus forming a uniform and thin metallic barrier layer may be facilitated even in porous ultra low-k dielectric materials. In one illustrative embodiment, a plasma may be applied to the exposed parts of a low-k dielectric material. Dependent on the particular material of the low-k dielectric material and the used parameters of the plasma, the surface may be charged positively or negatively. In cases where the damages at the sidewalls are small enough, it might be sufficient to introduce negative or positive charges onto the surface to achieve a smooth and uniform subsequent barrier layer. The negative and positive charges will accumulate at protruding parts of damages in the sidewall and an appropriate adjustment of sputter conditions in the subsequent deposition of the barrier layer will lead to a preferred deposition of barrier material particles in the recessed portions of the damaged sidewall, thus leading to smoothing out and densification of the surface. For instance, if the plasma is adjusted such that protruding parts of the damages of the sidewalls are charged with positive charges and the subsequent deposited metallic barrier particles are also positively charged, the metallic barrier particles will tend to deposit in negatively charged or neutral recess portions of the damaged surface. Vice versa, protruding parts may be provided with negative charges by appropriate plasma adjustments and the metallic barrier particles may also be negatively charged which would lead to a preferred deposition of charged metallic barrier particles in the recessed portions of the damaged side-walls. In an alternative, sidewalls of the trenches and the vias may also be discharged, for instance, by introducing appropriate ions into the plasma to saturate any free charges at the surface of the sidewalls. By this procedure, again protruded portions of the damaged sidewall will be preferably discharged and possible remaining charges will be left in the recessed portions. Appropriately charged metallic barrier particles will again preferably deposit in the recessed portions, thus leading to smoothing and densifying the surface of the damaged side-walls. In order to improve the efficiency of the above three alternative methods, these methods may also be combined. For instance, positively charging the surface with subsequent depositing positively charged metallic barrier materials followed by negatively charging the surface with subsequently depositing positively charged barrier particles followed by a discharging of the surface with subsequent deposition of charged or uncharged metallic barrier particles may be considered. As it is appreciated by the person skilled in the art, any combination of these steps are possible to achieve a dense and smooth surface depending on the used materials and surface topology.

In cases of more severe damages of the sidewalls, a complete coverage of the exposed surfaces with a protection layer may be contemplated in a further illustrative embodiment. For instance, a thin layer of dielectric material, like silicon oxide (SiO₂), silicon carbide (SiC) or a silicon nitride (Si₃N₄), may be deposited, for instance, by CVD or PVD techniques, or by adding appropriate reactive gases to a plasma.

For even more severe sidewall damages, for instance, in porous ultra low-k materials, a layer of a polymer thin film that withstands temperatures of subsequent process steps may be deposited. For instance, if subsequent annealing requires a temperature of 300° C., the polymer should withstand such temperatures.

In an illustrative embodiment, wet chemical polymerization processes are particularly suitable for a protection coating. For instance, any wet chemical silane chemistry is suitable for filling recesses and uneven parts and pores of the sidewall of the vias and the trenches. Due to the low viscosity of monomer and olygomer solutions of polymer precursors, the monomer/olygomer solutions may move, due to capillary forces, into recessed portions and pores of the damaged sidewall. After removing the monomer/olygomer solution from the via and trenches, the monomer/olygomer solution remains in the recessed portions due to the capillary forces and may begin with crosslinking to form a thin hardcoat thereby smoothing out and sealing the damaged surface of the sidewalls. Besides well-known wet chemical silane chemistry, thermal curable polycyanurate may be used which has a low viscosity in the liquid state of the monomer/olygomer solution and which may be further hardened in a thermal curing process in a temperature range between 100-300° C. Further, polycyanurate has a low dielectric constant such that the dielectric properties of the low-k dielectric material is less influenced by the dielectric properties of the polycyanurate.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of manufacturing a semiconductor device, comprising:
depositing a low-k dielectric material onto a surface;
forming at least one of a via and a trench into the low-k dielectric material, said via and trench having sidewalls;
densifying and smoothing the sidewalls of said via and said trench; and
after densifying and smoothing the sidewalls, coating the sidewalls with a barrier layer.

2. The method of claim 1, wherein densifying and smoothing the sidewalls of said via and said trench comprises at least one of coating the sidewalls with a dielectric material, introducing surface charges and saturating surface charges.

3. The method of claim 2, wherein coating the sidewalls with a dielectric material comprises:
forming a thin film on the semiconductor device to cover a top surface of the low-k dielectric material, the sidewalls of said via and said trench and a bottom surface of said via and said trench; and
removing said thin film from the top surface of the low-k dielectric material and the bottom surface of said via and said trench by an anisotropic etching process.

4. The method of claim 3, wherein forming the thin film comprises reacting the sidewalls with at least one of oxygen, nitrogen and carbon.

5. The method of claim 3, wherein forming the thin film comprises depositing at least one of silicon oxide (SiO₂), silicon nitride (Si₃N₄) and silicon carbide (SiC).

6. The method of claim 3, wherein forming the thin film comprises depositing a polymer that withstands temperatures of less than 300° C. by filling a low viscosity monomer/olygomer solution into the via and trench and crosslinking the monomer/olygomer on the sidewall surface.

7. The method of claim 6, wherein said polymer is selected from a group consisting of silane and polycyanurate.

8. The method of claim 1, wherein protection treatment of the sidewalls of said via and said trench comprises plasma treatment.

9. The method of claim 8, wherein plasma treatment includes introducing a reactive gas for at least one of introducing surface charges and saturating surface charges.

10. The method of claim 1, wherein the via has an aspect ratio of more than 5 and a diameter of less than 0.1 μm.

11. The method of claim 1, wherein the low-k material is at least one of fluorine doped silicon dioxide, carbon doped silicon dioxide, porous silicon dioxide, porous carbon doped silicon dioxide, spin-on organic polymeric dielectrics, spin-on silicone based polymeric dielectric and porous polymeric dielectrics.

12. The method of claim 11, wherein the organic polymeric dielectric material is selected from the group comprising Dow Chemical's SiLK, polyimide, polynorbornenes, benzocyclobutene, and PTFE.

13. The method of claim 11, wherein the silicone based polymeric dielectric material is selected from the group comprising hydrogen silsesquioxane (HSQ) and methylsilsesquioxane (MSQ).

14. The method of claim 1, wherein the barrier layer is formed of a conductive material.

15. The method of claim 14, wherein the conductive material of the barrier layer is selected from the group consisting of cobalt, ruthenium, tantalum, tantalum nitride, indium oxide, titanium nitride, cobalt-tungsten-phosphorous compound, cobalt-tungsten-boron compound, cobalt-boron compound and molybdenum-nickel-boron compound.

16. The method of claim 1, wherein the barrier layer includes a chromium adhesion layer.

17. A method of manufacturing a semiconductor device having at least one metallization layer, each metallization layer comprising a layer of low-k dielectric material including at least one of a via and a trench formed in the layer of low-k dielectric material, the method comprising:
coating sidewalls of said via and said trench with a dielectric material, wherein coating the sidewalls comprises:
forming a thin film on the semiconductor device to cover a top surface of the low-k dielectric material, the sidewalls of said via and said trench and the bottom surface of said via and said trench; and
removing said thin film from a top surface of the low k-dielectric material and the bottom surface of said via and said trench by performing an anisotropic etching process to expose a wiring portion at the bottom surface of the via;
forming a barrier layer on the coated sidewalls; and
filling the via and the trench with a metal.

18. The method of claim 17, wherein forming the thin film comprises reacting the sidewalls with at least one of oxygen, nitrogen and carbon.

19. The method of claim 17, wherein forming the thin film comprises depositing at least one of silicon oxide (SiO₂), silicon nitride (Si₃N₄) and silicon carbide (SiC).

20. The method of claim 17, wherein forming the thin film comprises depositing a polymer with surface smoothing properties that withstands temperatures of less than 300° C.

21. The method of claim 20, wherein said polymer is selected from a group consisting of silane and polycyanurate.

22. A semiconductor device comprising at least one metallization layer, each metallization layer including at least one of a via and a trench formed in a layer of low-k dielectric material and filled with copper, wherein:
sidewalls of said via and said trench are coated with a thin film comprising at least one of silicon oxide (SiO₂), silicon nitride (Si₃N₄) and silicon carbide (SiC) and a polymer that withstands temperatures of less than 300° C.; and
a conductive barrier layer is formed on the thin film.

23. The semiconductor device of claim 22, wherein said polymer is selected from a group consisting of silane and polycyanurate.

24. The semiconductor device of claim 22, wherein the conductive material of the barrier layer is selected from the group consisting of cobalt, ruthenium, tantalum, tantalum nitride, indium oxide and titanium nitride.

25. The semiconductor device of claim 22, wherein the via has an aspect ratio of more than 5 and a diameter of less than 0.1 μm.

26. The semiconductor device of claim 22, wherein the low-k material is at least one of fluorine doped silicon dioxide, carbon doped silicon dioxide, porous silicon dioxide, porous carbon doped silicon dioxide, spin-on organic polymeric dielectrics, spin-on silicone based polymeric dielectric and porous polymeric dielectrics.
